(19) United States
(12) Patent Application Publication
(10) Pub. No.: US 2025/0212701 A1
(43) Pub. Date: Jun. 26, 2025

(54) QUANTUM DEVICE WITH STACKED QUBITS AND WITHOUT DIAGONAL COUPLING

(71) Applicant: COMMISSARIAT A L'ENERGIE ATOMIQUE ET AUX ENERGIES ALTERNATIVES, Paris (FR)

(72) Inventor: Heimanu NIEBOJEWSKI, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 18/990,786

(22) Filed: Dec. 20, 2024

(30) Foreign Application Priority Data
Dec. 22, 2023 (FR) FR2315160

(51) Int. Cl. H10N 60/10; B82Y 10/00; H10N 60/01

(52) U.S. Cl. CPC H10N 60/128; H10N 60/01; H10N 60/11; B82Y 10/00

(57) ABSTRACT

A quantum electronic device including a first set of semiconductor regions, a second set of semiconductor regions, the first set of semiconductor regions being disposed opposite the second set of semiconductor regions. Further, at least one dielectric region separates the first set of semiconductor regions from the second set of semiconductor regions, said dielectric region being provided with a heterogeneous composition so as to prevent electrostatic coupling between a first lower semiconductor region and a second upper semiconductor region, and so as to prevent electrostatic coupling between a first semiconductor region and a second lower semiconductor region.

### TECHNICAL FIELD AND PRIOR ART

The present application relates to the field of quantum devices wherein at least one item of quantum information based on a given quantum state from at least two measurable levels is used. This quantum state is referred to as qubit or quantum bit.

One particular type of qubit is the spin qubit when the intrinsic degree of freedom of the spin of individual electrons is used for coding the quantum information.

Qubits can be formed in a semiconductor material within nano-sized electrostatically and/or physically defined confinement structures. These confinement structures are typically referred to as “quantum dots”.

A quantum dot behaves like a potential well confining one or more elementary charges (electrons or holes) in a semiconductor region.

To measure the state of a qubit, proceeding with a spin/charge conversion that makes it possible to convert the spin state of the charged particles into a state of charge of the quantum dots containing said particles is known. It is then necessary to measure this state of charge in order to deduce therefrom the spin state of the charged particles before conversion. For this, a means of measuring the state of charge is generally disposed facing or in proximity to each quantum dot.

A qubit can in particular be read using another quantum dot referred to as a “reading island” or “detection island” coupled to that of the qubit intended to be read. These two elements form two potential wells separated by a potential barrier.

Devices in which the detection islands and quantum dots are disposed facing each other and in one and the same plane parallel to the main plane of a substrate on which the quantum dots and detection islands are formed are known.

The document by R Pillarisetty “High Volume Electrical Characterization of Semiconductor Qubits”, 2019 IEEE International Electron Devices Meeting (IEDM) proposes, for example, a device with quantum dots formed in a first elongate semiconductor block (“fin”) and detection islands formed in a second elongate semiconductor block parallel to the first block.

The problem is posed of producing a new quantum device that is preferably improved in terms of integration density while retaining good detection sensitivity.

### DESCRIPTION OF THE INVENTION

According to one aspect, the present invention relates to a quantum electronic device provided with a substrate, this substrate being clad:
with a first set of semiconductor regions comprising at least one first lower semiconductor region and at least one first upper semiconductor region, superimposed on, and separated from, the first lower semiconductor region by means of a first so-called “separation” zone,
with a second set of semiconductor regions comprising at least one second lower semiconductor region and at least one second upper semiconductor region, superimposed on, and separate from, the first lower semiconductor region by means of a second so-called “separation” zone,
the first set of semiconductor regions being disposed opposite the second set of semiconductor regions so that the first lower semiconductor region is disposed facing the second lower semiconductor region and so that the first upper semiconductor region is disposed facing the second upper semiconductor region,
at least one dielectric region separating the first set of semiconductor regions from the second set of semiconductor regions, said dielectric region (RD) having a heterogeneous composition.

Advantageously, the dielectric region is configured so as to allow an electrostatic coupling between a first semiconductor region from the semiconductor regions of the first set and a given semiconductor region from the semiconductor regions of the first set or of the second set, the first semiconductor region and the given semiconductor region being located on one and the same first axis, the dielectric region being configured so as to prevent an electrostatic coupling between the first semiconductor region and another given semiconductor region distinct from the given semiconductor region, the other given semiconductor region being located on a second axis passing through the first semiconductor region, the second axis being distinct from the first axis and non-collinear with the first axis.

According to a possible implementation, the dielectric region can be configured so as to allow an electrostatic coupling between the first lower semiconductor region and the second lower semiconductor region and so as to allow an electrostatic coupling between the first upper semiconductor region and the second upper semiconductor region.

The dielectric region, through the heterogeneous composition thereof, can also be designed so as to prevent an electrostatic coupling between the first lower semiconductor region and the second upper semiconductor region and so as to prevent an electrostatic coupling between the first upper semiconductor region and the second lower semiconductor region.

Thus a device is used with quantum dots that can be disposed in different planes and here a coupling is allowed between these quantum dots and semiconductor regions or detection islands disposed opposite or facing while preventing a coupling with regions of different levels.

Advantageously, the dielectric region between the first set of semiconductor regions and the second set of semiconductor regions is designed with a heterogeneous dielectric composition so that, in a central portion located between the first lower semiconductor region and the second upper semiconductor region and between the first upper semiconductor region and the second lower semiconductor region, the dielectric region is formed by an empty space, or has a composition with a given dielectric material and a given dielectric constant k2, and so that, in another portion located between the first lower semiconductor region and the second lower semiconductor region or between the first upper semiconductor region and the second upper semiconductor region, the dielectric region has a second composition and a higher relative dielectric constant than the given dielectric constant k2.

According to one embodiment, the dielectric region between the first set of semiconductor regions and the second set of semiconductor regions can be formed:
by a lower dielectric portion arranged between the first lower semiconductor region and the second lower semiconductor region,
by an upper dielectric portion located between the first upper semiconductor region and the second upper semiconductor region,
by a central dielectric portion, arranged between the lower dielectric portion and the upper dielectric portion, the lower dielectric portion, the central dielectric portion and the upper dielectric portion being superimposed,
the central dielectric portion being made from a given dielectric material having a first dielectric constant k2, the lower dielectric portion and the upper dielectric portion being based on one or more dielectric materials different from said given dielectric material and with respective dielectric constant or constants greater than k2.

According to another possibility of implementation, the dielectric region with a heterogeneous composition between the first set of semiconductor regions and the second set of semiconductor regions is formed:
by at least one dielectric material having a dielectric constant k1 cladding each of the first and second lower and upper semiconductor regions, so as to form lower insulating envelopes against the first and second lower semiconductor regions and upper insulating envelopes against the first and second upper semiconductor regions, and
at least one insulating space between an upper insulating protrusion located on the first or second upper semiconductor region and a lower insulating protrusion located on the first or second lower semiconductor region, the insulating space being:
filled in by a given dielectric material having a dielectric constant k2, such that k2<k1, or
being an empty space.

According to one variant, the dielectric region can be provided with a heterogeneous composition so as to allow an electrostatic coupling between the first lower semiconductor region and the second upper semiconductor region and so as to allow an electrostatic coupling between the first upper semiconductor region and the second lower semiconductor region, and so as to prevent an electrostatic coupling between the first lower semiconductor region and the second lower semiconductor region and to prevent an electrostatic coupling between the first upper semiconductor region and the second upper semiconductor region.

In this case, advantageously, the dielectric region between the first set and the second set of semiconductor regions can be formed:
by a lower dielectric portion arranged between the first lower semiconductor region and the second lower semiconductor region,
by an upper dielectric portion located between the first upper semiconductor region and the second upper semiconductor region,
by a central dielectric portion, arranged between the lower dielectric portion and the upper dielectric portion, the lower dielectric portion, the central dielectric portion and the upper dielectric portion being superimposed,
the central dielectric portion being made from a given dielectric material having a first dielectric constant k2, the lower dielectric portion and the upper dielectric portion being based on at least one dielectric material different from said given dielectric material and with a respective dielectric constant less than k2.

According to another variant, the dielectric region can be configured so as to allow an electrostatic coupling between the first lower semiconductor region and the first upper semiconductor region and so as to allow an electrostatic coupling between the second lower semiconductor region and the second upper semiconductor region, said dielectric region furthermore being designed so as to prevent an electrostatic coupling between firstly the first lower semiconductor region and secondly respectively the second upper semiconductor region and the second lower semiconductor region, and so as to prevent an electrostatic coupling between firstly the first upper semiconductor region and secondly the second lower semiconductor region and the second upper semiconductor region.

According to a particular embodiment of this variant, the dielectric region between the first set of semiconductor regions and the second set of semiconductor regions can be designed with a heterogeneous dielectric composition so that, between the first set of semiconductor regions and the second set of semiconductor regions, the dielectric region is formed by a juxtaposition of a first dielectric portion, a central dielectric portion and a second dielectric portion, the central dielectric portion being arranged between the first dielectric portion and the second dielectric portion, the first dielectric portion, the second direction portion and the central dielectric portion each being arranged facing the first lower semiconductor region, the first upper semiconductor region, the second lower semiconductor region and the second upper semiconductor region, the central dielectric portion being made from a given dielectric material having a first dielectric constant, the first electric portion and the second electric portion being based on at least one dielectric material different from said given dielectric material and with a respective dielectric constant lower than that of the central dielectric portion.

According to a particular embodiment, the separation zones can be designed so as to allow an electrostatic coupling between the first lower semiconductor region and the first upper semiconductor region and so as to allow an electrostatic coupling between the second lower semiconductor region and the second upper semiconductor region.

According to a possibility of implementation of the device, the first lower semiconductor region and the first upper semiconductor region are regions respectively of a lower semiconductor bar and of an upper semiconductor bar, the lower semiconductor bar and the upper semiconductor bar extending parallel to a first direction parallel to a main plane of the substrate. Thus a plurality of quantum dots can be distributed along one and the same first semiconductor bar and a plurality of detection islands can be distributed along a second semiconductor bar located facing the first semiconductor bar.

Advantageously, the quantum electronic device can furthermore comprise: a plurality of control gates of the lower semiconductor bar and of the upper semiconductor bar, the control gates extending in a second direction producing a non-zero angle with the first direction and advantageously orthogonal to the first direction.

According to an embodiment, the quantum electronic device can furthermore comprise:
a first group of superimposed gates comprising at least one first lower gate and one first upper gate superimposed on and separated from the first lower gate by an insulation zone, the first lower gate and the first upper gate being disposed against, and facing, respectively the first lower semiconductor region and the first upper semiconductor region so as to exert respectively an electrostatic control of the first lower semiconductor region and of the first upper semiconductor region,
a second group of superimposed gates comprising at least one second lower gate separated from a second upper gate superimposed on and separated from the second lower gate by a second insulation zone, the second lower gate and the second upper gate being disposed against, and facing, respectively the second lower semiconductor region and the second upper semiconductor region so as to exert respectively an electrostatic control of the second lower semiconductor region and of the second upper semiconductor region, the first group of superimposed gates and the second group of superimposed gates being disposed on either side of the first set of semiconductor regions and of the second set of semiconductor regions.

According to another aspect, the present invention relates to a method for making a quantum electronic device and in particular a quantum device as defined above.

Another aspect of the invention provides a method for manufacturing a quantum device as defined above and wherein forming the first set of semiconductor regions and of the second set of semiconductor majors comprises the steps of:
producing on the substrate a structure formed by a superimposition of layers composed of an alternation of layers based on a first given material, and of layers based on a second material, the second material being semiconductive, the first given material being able to be etched selectively with respect to the second given material,
producing a separation trench extending mainly in a direction parallel to the first direction by etching said superimposition of layers so as to divide said structure into a first portion and a second portion, the first portion and the second portion extending parallel to the first direction, the semiconductor regions of the first set being semiconductor regions of the first portion and formed from the second given material, the semiconductor regions of the second set being semiconductor regions of the second portion and formed from a second given material, and wherein the heterogeneous dielectric region is next formed in the separation trench between the first portion and the second portion of the structure.

Forming the second dielectric region can comprise the steps of:
depositing in the separation trench a first dielectric material to form a lower dielectric portion arranged between the first lower semiconductor region and the second lower semiconductor region,
depositing in the separation trench a second layer based on a given dielectric material different from the first dielectric material and with a given dielectric constant k2 lower than that of the first dielectric material to form a central dielectric portion,
depositing in the separation trench a first dielectric or a third dielectric material with a dielectric constant greater than that of the given dielectric material to form an upper dielectric portion arranged between the first upper semiconductor region and the second upper semiconductor region.

According to a possibility of implementation, after depositing the first dielectric material and prior to depositing the given dielectric material: a partial removal of the first dielectric material is implemented in the trench, and wherein, after the given dielectric material is deposited and prior to the formation of the upper dielectric portion, a partial removal of the given dielectric material is implemented.

According to a possibility of implementation, forming the second heterogeneous dielectric region can comprise steps of:
growing, by epitaxy on the first lower semiconductor region, on the first upper semiconductor region, on the second lower semiconductor region and on the second upper semiconductor region, a sacrificial semiconductor material so as to preserve an empty space between the first portion and the second portion of the structure,
filling the empty space by means of a given dielectric material with a given dielectric constant k2,
removing the sacrificial semiconductor material selectively with respect to that of the first lower semiconductor region, of the first upper semiconductor region, of the second lower semiconductor region and of the second upper semiconductor region, in order to release volumes around respectively the first lower semiconductor region, the first upper semiconductor region, the second lower semiconductor region and the second upper semiconductor region,
filling in the volumes by means of a dielectric material different from the given dielectric material and having a dielectric constant k1 greater than k2.

According to another possibility of implementation, the method for forming the dielectric region can comprise steps of:
epitaxial growth, on the first lower semiconductor region, the first upper semiconductor region, the second lower semiconductor region and the second upper semiconductor region, of a sacrificial semiconductor material so as to preserve an empty space between the first portion and the second portion of the structure,
filling said empty space by means of a given dielectric material,
removing the sacrificial semiconductor material selectively with respect to that of the first lower semiconductor region, of the first upper semiconductor region, of the second lower semiconductor region and of the second upper semiconductor region, in order to release volumes around respectively the first lower semiconductor region, the first upper semiconductor region, the second lower semiconductor region and the second upper semiconductor region,
filling in the volumes by means of a dielectric material different from the given dielectric material and able to be etched selectively with respect to said given dielectric material,
removing said given dielectric material selectively with respect to said other dielectric material.

### BRIEF DESCRIPTION OF THE DRAWINGS

The present invention will be better understood upon reading the description of exemplary embodiments provided merely for illustrative purposes and which are in no way limiting, with reference to the appended drawings wherein:

FIG. 1 illustrates an example of a quantum device provided with semiconductor regions superimposed and facing each other.

FIG. 2A illustrates an example embodiment wherein the quantum device is provided with a plurality of superimposed pairs of gates and wherein the semiconductor regions are distributed along superimposed semiconductor bars.

FIG. 2B serves to illustrate a superimposition of semiconductor bars in the quantum device.

FIGS. 3 and 4 illustrate an example embodiment of the quantum device wherein an insulating space is provided between adjacent groups of gates and distributed along superimposed semiconductor bars.

FIGS. 5, 6A and 6B illustrate an exemplary embodiment of a semiconductor structure of an active region for a quantum device with two sets of superimposed semiconductor regions.

FIGS. 7, 8 and 9 illustrate an example embodiment of gate patterns.

FIGS. 10, 11, 12 and 13 illustrate an example embodiment of reservoirs of dopants.

FIGS. 14, 15, 16, 17, 18, 19A and 19B illustrate an example of producing superimposed gates from gate patterns.

FIGS. 20A and 20B Illustrate an exemplary embodiment of a separation trench to separate a semiconductor structure of active zone into distinct portions arranged face to face with each other and including superimposed semiconductor regions.

FIGS. 21 and 22 illustrate an exemplary embodiment of dielectric separation zones interposed between superimposed semiconductor regions.

FIGS. 23A and 23B illustrate an exemplary embodiment of an intermediate dielectric region between a first portion and a second portion of a structure of active zone.

FIG. 24 illustrates a particular embodiment of the quantum device as implemented according to the invention, the device here being provided with an intermediate dielectric region having a heterogeneous composition in order to allow an electrostatic coupling between semiconductor regions located at the same level and facing one another while preventing an electrostatic coupling between firstly semiconductor regions of the first portion and secondly semiconductor regions of the second portion located in different levels.

FIGS. 25 to 29 illustrate a first example of a method for manufacturing a quantum device according to the invention.

FIG. 30 illustrates another particular embodiment of a quantum device according to the invention.

FIGS. 31 to 35 illustrate a second example of a method for manufacturing a quantum device according to the invention.

FIGS. 36 to 40 illustrate a third example of a method for manufacturing the second particular embodiment of the quantum device.

FIGS. 41 and 42 illustrate an exemplary embodiment of exchange gates.

Identical, similar or equivalent parts of the various figures bear the same reference numerals so as to make it easier to switch from one figure to another.

The various parts shown in the figures are not necessarily drawn to a uniform scale, to make the figures more legible.

FIG. 43 illustrates a variant embodiment of the device allowing an electrostatic coupling between regions between firstly semiconductor regions of the first portion and secondly semiconductor regions of the second portion located in different levels while preventing an electrostatic coupling between semiconductors located at the same level and facing each other.

FIGS. 44 to 48 illustrate a particular example of a method for producing such a variant.

FIG. 49 illustrates a variant embodiment of the device allowing an electrostatic coupling between superimposed regions while preventing a coupling with semiconductor regions of another set of superimposed semiconductor regions.

In addition, in the following description, terms which depend on the orientation of the structure such as “above”, “below”, “lower”, “upper”, “juxtaposed”, “superimposed” apply on the assumption that the structure is oriented as illustrated in the figures.

### DETAILED DESCRIPTION OF PARTICULAR EMBODIMENTS

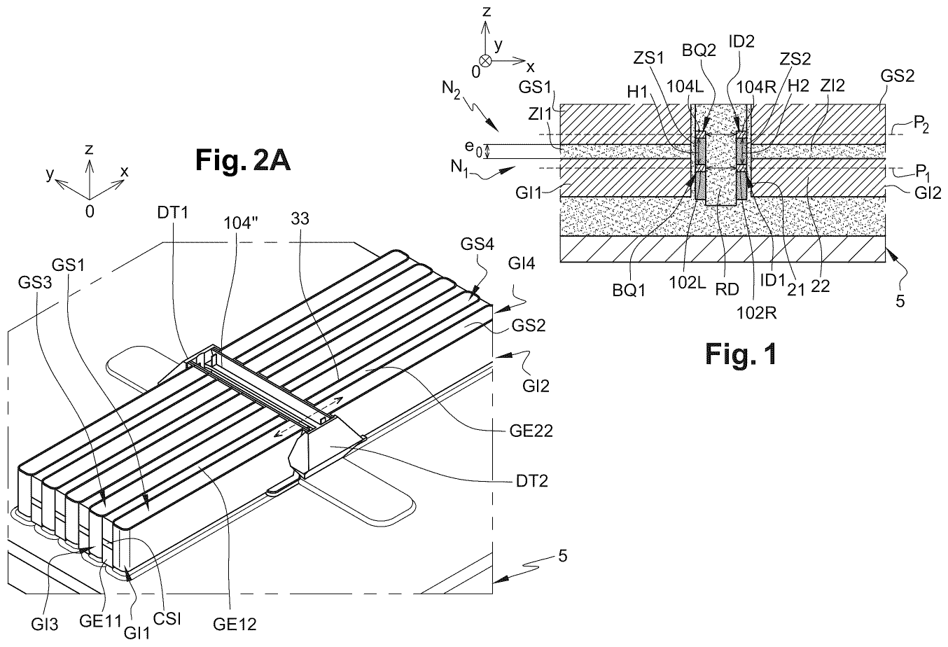

FIG. 1 is firstly referred to as an exemplary embodiment of a quantum device.

The device is arranged on a substrate 5, which may be, for example, of the semiconductor-on-insulator type, in particular of the SOI (silicon-on-insulator) type or of the bulk type, for example of silicon.

The device is here provided with quantum dots BQ1, BQ2 formed in a first set of superimposed semiconductor regions 102L, 104L, for example of silicon or germanium. A quantum dot BQ1 is thus made in a first so-called “lower” semiconductor region 102L, while another quantum dot BQ2 disposed above the first lower semiconductor region is formed in a first so-called “upper” semiconductor region 104L.

The quantum dots BQ1 and BQ2 each confine at least one elementary charge (electron(s) or hole(s)). Preferably, each quantum dot BQ1, BQ2 herein includes a single elementary charge. The spin of this charge in particular an electron, can be provided for coding the quantum information. In this case, the qubits associated with quantum dots BQ1, BQ2 are spin qubits.

To enable detection of a quantum state also referred to as “state of charge” of the quantum dots BQ1, BQ2, a charge detection structure is provided in proximity to and in this example in front of the quantum dots BQ1, BQ2.

This detection structure comprises detection islands ID1, ID2 formed in a second set of superimposed semiconductor regions 102R, 104R, typically based on the same semiconductor material as the regions 102L, 104L. A detection island ID1 is thus made in a second lower semiconductor region 102R which faces the first lower semiconductor region 102L, while another detection island ID2 is formed in a second upper semiconductor region 104R disposed above the second lower semiconductor region 102R and faces the first upper semiconductor region 104L.

The first semiconductor regions 102L, 104L are thus each designed to form a qubit, while the second semiconductor regions 102R, 104R are dedicated to reading the qubits.

In the particular exemplary embodiment illustrated, the lower semiconductor regions 102L, 102R are arranged in one and the same first plane P1, while the upper semiconductor regions 104L, 104R are arranged in one and the same second plane P2, the first and second planes P1 and P2 being parallel to a main plane of the substrate 5 (i.e. a plane defined throughout the description as a plane passing through the substrate 5 and which is parallel to the plane [0; x; y] of the orthogonal reference frame [0; x; y; °z]).

The device is also provided with at least one dielectric region RD based on at least one dielectric material located between, on the one hand, the superimposition of quantum dots BQ1, BQ2 and, on the other hand, the superimposition of islands ID1, ID2.

In this exemplary embodiment, the operation of the device is based on capacitive coupling, also referred to as “electrostatic coupling”, between each quantum dot BQ1, BQ2 and a detection island ID1, ID2 arranged opposite the quantum dot BQ1, BQ2. In this case, the dielectric material(s) of the dielectric region RD are selected in particular in terms of relative permittivity or dielectric constant and the dimensions D1, D2 (corresponding respectively to the distance between upper semiconductor regions and the distance between lower semiconductor regions) of this dielectric region RD for achieving such electrostatic coupling. Such coupling can result in a measurable useful signal which is greater than a parasitic signal and which can be in the order of several fF (femtofarads).

For example, for achieving electrostatic coupling between a quantum dot and an island facing this dot, the dielectric region RD can be formed from SiO₂, SiN, Al₂O₃, HfO₂, and with dimensions D1, D2 of between 10 nm and 60 nm, for example, advantageously between 20 nm and 40 nm.

For achieving electrostatic control of quantum dots and detection islands, provision is made for gates formed by a conductive or semiconductive block of gate material 22, for example polysilicon, against a dielectric gate layer 21 disposed between the gate block and the semiconductive regions. The arrangement proposed in FIG. 1 herein has the particularity of providing a same gate dielectric layer 21 common to the two superimposed gates GI1, GS1 and semiconductor regions 102L, 104L.

The quantum dots BQ1, BQ2 are controlled by a first group of superimposed gates GI1, GS1, each gate GI1, GS1 being herein disposed against a quantum dot BQ1, BQ2. A first so-called “lower” gate GI1 for electrostatic control of the first lower semiconductor region 102L is located in the first plane P1, while a first so-called “upper” gate GS1 for electrostatic control of the first upper semiconductor region 104L is located in the second plane P2.

The first upper gate GS1 is superimposed on and separated from the first lower gate GI1 via a first insulation zone ZI1. This first insulation zone ZI1 between the lower GI1 and upper GS1 gates is typically of insulating material and preferably of sufficient thickness e₀ to electrically insulate the gates GI1, GS1 from each other. For example, the first insulation zone ZI1 is formed from SiO₂ and has a thickness e₀ which may be between 5 nm and 20 nm, for example.

For achieving electrostatic control of the semiconductor regions 102R, 104R, a second group of superimposed gates GI2, GS2 is provided, each gate GI2, GS2 being herein juxtaposed against a semiconductor region 124a, 124b. A second lower gate GI2 is located in the first plane P1, while a second upper gate GS2 is located in the second plane P2 and insulated from the lower gate GS2 via an insulation zone Z12. This second insulation zone ZI2 of the lower GI2 and upper GS2 gates is advantageously provided with a thickness and material similar to that of the first insulation zone ZI1.

In this exemplary embodiment, there is thus advantageously an alignment of the lower gates GS1, GR1 and the lower semiconductor regions 102L, 102R in one and the same plane P1 and an alignment of the upper gates GS2, GR2 and the upper semiconductor regions 104L, 104R in one and the same upper plane P2 distinct from the plane P1.

According to a possible implementation of the device, it can be provided that each qubit stage is independent of the other stages, thus preventing electrostatic coupling between the first lower semiconductor region 102L and the first upper semiconductor region 104L. Electrostatic coupling between the second lower semiconductor region 102R and the second upper semiconductor region 104R is then also typically prevented. In this case, only horizontal interactions (in other words in directions parallel to the main plane of the substrate) between quantum dots BQ1, BQ2 and detection islands ID1, ID2 are promoted.

To enable the lower stage to be insulated from the upper stage, so-called “separation” zones ZS1, ZS2 arranged respectively between the first lower and upper semiconductor regions 102L and 104L and between the second lower and upper semiconductor regions 102R and 104R are provided, herein preferably of dielectric material, for example SiO₂, and with a sufficient thickness (also referred to as height) H1, H2, for example of at least 30 nm, and typically of between 30 nm and 100 nm.

It can be envisaged integrating several other quantum dots in the lower stage N₁ in which quantum dot BQ1 is located and several other quantum dots in the upper stage N₂ in which quantum dot BQ2 is located. In this case, the first lower semiconductor region 102L may be a region of a semiconductor block typically in the form of a bar (cross-section view in FIG. 1), for example parallelepipedal or substantially parallelepipedal in shape and referred to as the first lower semiconductor bar, in which other semiconductor regions forming other quantum dots each controlled by a gate are arranged.

Similarly, the first upper semiconductor region 104L may be formed in another semiconductor bar referred to as the first upper semiconductor bar in which other semiconductor regions forming other quantum dots each controlled by a gate are arranged. The second lower semiconductor region 102R may be a region of a second lower semiconductor bar located in the same first plane P1 as the first lower semiconductor bar and in which other semiconductor regions forming other detection islands each controlled by a gate are arranged. Similarly, the second upper semiconductor region 104R may be formed in a second upper semiconductor bar in which other semiconductor regions forming other detection islands each controlled by a gate are disposed. A partial perspective view given in FIG. 2B serves to illustrate a superimposition of bars 104′, 104″ in which the second upper semiconductor region 104R and the second lower semiconductor region 102R are formed respectively. The bars can be produced here from a superimposition of distinct layers of the substrate.

The first and second lower and upper semiconductor bars all extend in a first direction (direction orthogonal to the plane of FIG. 1 and parallel to the axis y of the orthogonal reference frame [0; x; y; °z]).

As can be seen from the exemplary embodiment illustrated in FIG. 2A (where the dielectric region RD is not shown for more legibility and only the second upper bar 104″ is visible) other groups of superimposed gates can be provided to control a lower and upper row of quantum dots as well as a lower and upper row of detection islands. The various groups of gates are distributed in the first direction along the bars and the gates typically extend in a second direction orthogonal to the first direction (and parallel to the axis x of the orthogonal reference frame [0; x; y; °z]).

Gates GI3, GS3 of a third group of superimposed gates, juxtaposed with the first group of superimposed gates GI1, GS1 (FIG. 2A) are thus dedicated to electrostatic control of, respectively, a third lower semiconductor region of the first lower semiconductor bar and a third upper semiconductor region of the first upper semiconductor bar. A fourth group of superimposed gates GI4, GS4 juxtaposed with the second group of superimposed gates GI2, GS2 is herein also provided, to control respectively a fourth lower semiconductor region of the second lower semiconductor bar and a fourth upper semiconductor region of the second upper semiconductor bar.

Advantageously, the device can be further provided with dopant reservoirs DT1 and DT2 at the ends of the lower and upper rows of quantum dots and detection islands. These dopant reservoirs can be in the form of blocks, typically of doped semiconductor material, for example phosphorus-doped silicon or boron-doped silicon germanium. In the particular exemplary embodiment illustrated, each block forming a dopant reservoir DT1, DT2 is connected to one end of the set of semiconductor bars.

Advantageously, exchange electrodes GE11, GE12, GE22 also referred to as “exchange gates” can be provided in inter-gate spaces. In the particular exemplary embodiment of FIG. 2A, rather than a single exchange electrode in one and the same inter-gate space, a pair of exchange electrodes GE11, GE12 superimposed in one and the same inter-gate space is advantageously provided.

The exchange electrodes GE11, GE12 mainly extend in a direction parallel to that in which the gates GI1, GS1, GI3, GS3 extend and which is preferably orthogonal to the first direction (the first direction being parallel to the axis y), in other words to the direction in which the semiconductor bars accommodating the detection islands and quantum dots extend. Each exchange electrode is typically separated from adjacent gates via an insulating spacer layer 33.

The arrangement of the exchange electrodes GE11, GE12 can be similar to that of the gates GS3, GI3 or GS1, GI1, so that an upper exchange electrode GE12 is disposed above a lower exchange electrode GE11 and insulated from this lower exchange electrode GE11 by the insulating layer an insulating separation layer CSI. The exchange electrodes achieve charge exchanges between neighbouring quantum dots or between neighbouring detection islands distributed along one and the same semiconductor bar. Thus the exchange electrode GE11 enables charge exchange between a first lower semiconductor region controlled by the gate GI1 and a lower semiconductor region controlled by the gate GI3 and located on one and the same semiconductor bar as the first lower semiconductor region.

The implementation of exchange electrodes is optional, in particular when the pitch Δ of the gates is small, for example less than 40 nm. In this case, some of the gates can be used to control exchange between adjacent quantum dots or detection islands of one and the same semiconductor portion.

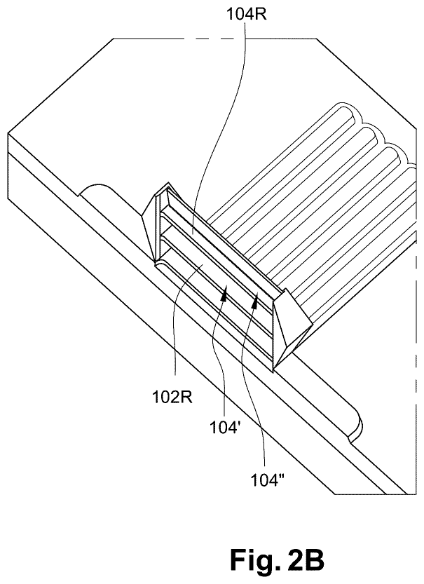

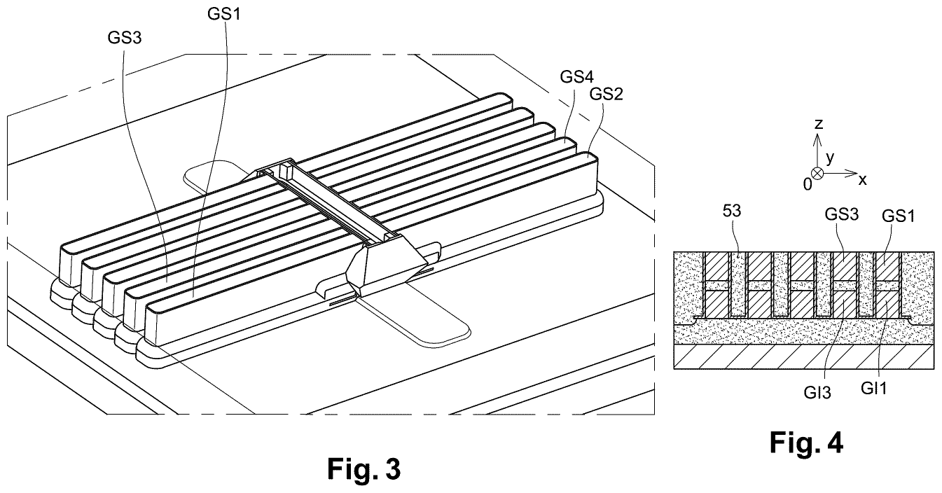

Thus, in an alternative embodiment illustrated in FIGS. 3 and 4, the inter-gate spaces are devoid of exchange electrodes.

In FIG. 4, which shows a transverse cross-section view of the gates GI1, GS1, GI3, GS3 (in other words, along a sectional plane orthogonal to the direction in which the gates extend), the inter-gate spaces are filled with insulating material 53.

In either of the exemplary embodiments just given, the device comprises two levels or stages N1, N2 of quantum dots and detection islands. However, the quantum device is not limited to this number and can integrate a higher number k (with k>2) of stages. Thus, more generally, a quantum device as implemented according to the invention can comprise a number of superimposed semiconductor region stages greater than two.

As an alternative to either of the previously described exemplary embodiments in which horizontal interactions between quantum dot BQ1 (or BQ2) and detection island ID1 (or ID2) are implemented, a device with both horizontal and vertical interactions between different levels of semiconductor regions may be provided. In this case, in particular, the separation zones ZS1, ZS2 illustrated in FIG. 1 can be provided with heights H1, H2 sufficiently low and based on a dielectric material with a sufficiently high dielectric constant to allow electrostatic coupling between the first lower semiconductor region 102L and the first upper semiconductor region 104L as well as between the second upper semiconductor region 102R and the second upper semiconductor region 104R. For example, for achieving electrostatic coupling between an upper semiconductor region 104L, 104R and a lower semiconductor region 102L, 102R, below, the separation zones ZS1, ZS2 can be formed based on high-k material (in other words with a high dielectric constant k), for example HfO₂, with a height H1, H2 of between 10 nm and 30 nm, for example, advantageously between 10 nm and 20 nm.

The capacitance, which is a measurable value, between 104L and 102L is greater than the capacitance measured between 104L and 104R.

A quantum device as described previously can adapt to different types of reading circuit. For example, it adapts to a transport reading circuit where the quantum state of a quantum dot is read by measuring current in the associated detection island. It also adapts to a reading circuit operating by reflectometry in which an RF signal is emitted in the direction of the detection island and then a reflected RF signal is detected in order to deduce the state of charge of a quantum dot associated with this detection island.

A quantum device as provided according to one or more of the previously described modes can be implemented using a thin-film microelectronic manufacturing method.

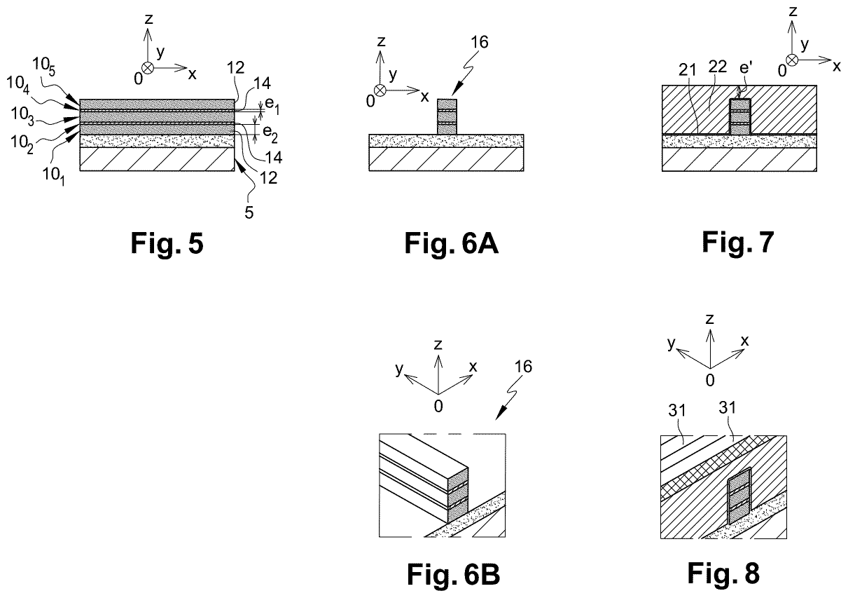

FIG. 5 is firstly referred to, and gives an example of a possible starting structure for making a quantum device according to the invention, herein including a substrate 5 which may be of the semiconductor-on-insulator type, for example SOI, or of the bulk type, for example of silicon.

A stack of layers formed by alternating layers 10₁, 10₃, 10₅ of a first material 12 and layers 10₂, 10₄ of a second material 14 is made on the substrate 5. The materials 12, 14 are typically semiconductor materials different from each other, the first material 12 being able to be etched selectively with respect to the second material 14. The particular exemplary embodiment illustrated in FIG. 5 provides for an odd number of layers, in particular five layers, but the method can be implemented with a different and in particular higher number of layers.

The layers 10₁, 10₃, 10₅ based on the first material 12 can advantageously be made with a thickness greater than that of the layers 10₂, 10₄ based on the second material 14, and which can be, for example, more than twice that of the layers 10₂, 10₄. The layers 10₁, 10₃, 10₅ based on the first material 12 can have a thickness e₁ of, for example, between 10 nm and 50 nm, while the layers 10₂, 10₄ have a thickness e₂ of, for example, between 5 nm and 20 nm.

For example, the first material 12 is silicon while the second material 14 is Si₁₋ₓGeₓ, with x>0, x being, for example, of the order of 30%. The layers 10₁, 10₃, 10₅, 10₂, 10₄ can be made by successive epitaxies.

When the first layer 10₁ is SiGe, this layer can optionally be formed from a surface layer of silicon on an SOI substrate by a Germanium enrichment method known to those skilled in the art, which consists in performing silicon epitaxy and then carrying out oxidation in order to diffuse germanium. Etching is then implemented so as to remove the oxide formed.

Then (FIGS. 6A and 6B), by etching the stack of layers 10₁, 10₂, 10₃, 10₄, 10₅ a structure of active zone 16 is defined, herein in the form of a block, typically oblong in shape, for example parallelepipedal, and which mainly extends in a first direction (direction orthogonal to the plane of FIG. 1 and parallel to the axis y of the orthogonal reference frame [0; x; y; °z]). This can be implemented by photolithography and etching the stack. Dry etching using fluorocarbon chemistry through a lithography mask (not represented) can be carried out for this purpose.

Gate patterns 25 are then formed from gate material 22 on either side of the structure 16.

For this purpose, first of all at least one layer 21 of at least one gate dielectric is deposited, for example of silicon oxide (SiO₂, or formed by a stack of silicon oxide and a high-k material such as for example HfO₂. This deposition is followed by that of at least one layer of conductive gate material 22, such as doped polysilicon (FIG. 7).

Preferably, after deposition and possible planarisation by CMP, a non-zero thickness e′ of conductive material 22, for example of the order of 50 nm, is left to protrude from the structure 16 of active zone.

Hard masks 31, typically dielectric and for example formed from a stack of SiN and SiO₂, are then made (FIG. 8).

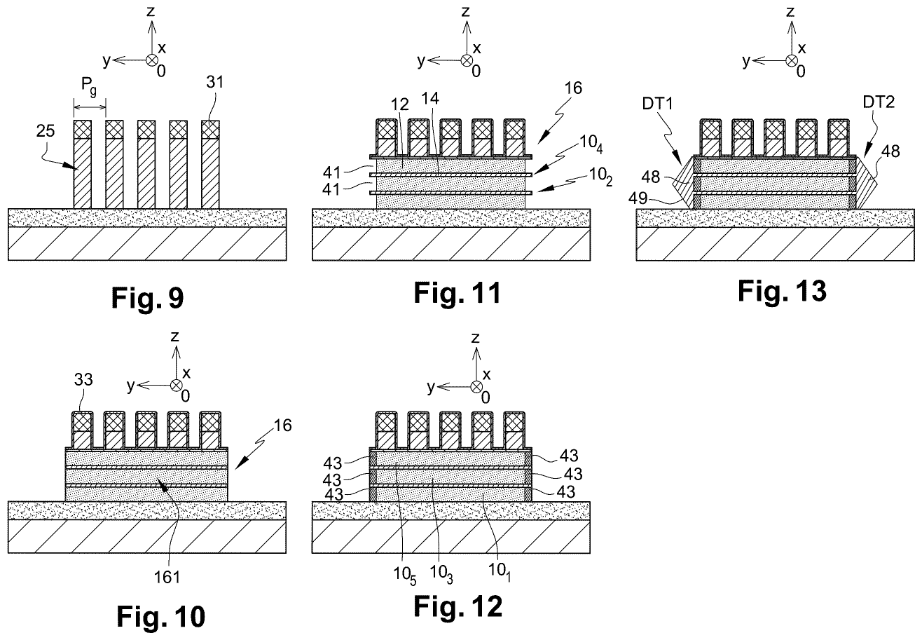

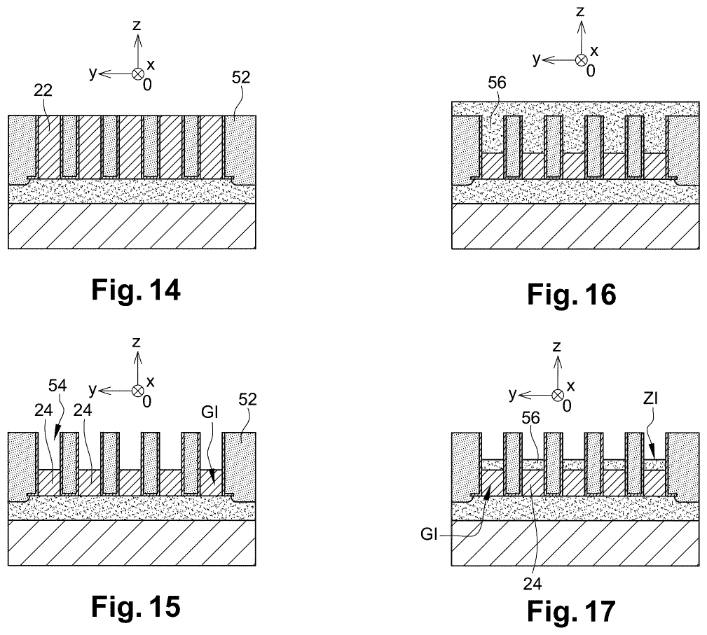

Then (FIG. 9 giving a cross-sectional view along a first plane parallel to reference [0; y; °z]) lithography and etching are carried out on the stack of gates to form an array of patterns 25 of parallel gates. The gate patterns 25 can be distributed at a small pitch Pg, for example of the order of 100 nm, or even smaller, for example 40 nm, to form a dense array of patterns 25.

After forming the gate patterns 25, dopant reservoirs DT1 and DT2 can advantageously be formed (FIGS. 10 to 13).

According to one method, a thin insulating spacer layer 33 is first conformally deposited on the gate patterns 25 (FIG. 10 giving a cross-sectional view along a second cutting plane parallel to the reference point [0; y; z] and distinct from the first cutting plane of FIG. 9), for example of silicon nitride and of a thickness which may be between 5 nm and 10 nm, for example. The thin insulating spacer layer 33 is arranged on and between the gate patterns 25, for example by an ALD (Atomic Layer Deposition) technique, in order to fill the inter-gate spaces without creating a filling defect.

Lithography is then carried out so as to remove portions of the thin insulating spacer layer 33 and extend this etching into parts of the structure 16 of active zone located around another part 161 in vertical alignment with the set of gate patterns 25 (FIG. 10 giving a cross-section view along a second cutting plane parallel to the reference [0; y; °z] and different from the first cross-sectional plane).

In order to form the dopant reservoirs in contact with the semiconductor layers 10₂, 10₄ in which it is intended to form the quantum dots and detection islands without bringing these reservoirs into contact with the other layers 10₁, 10₃, 10₅ of the structure, partial etching of the first material 12 selectively with respect to the second material 14 can advantageously be performed in order to create recesses 41 (FIG. 11) at flanks of the structure 16. For example, when the first material 12 is SiGe, this etching is for example performed by wet chemical etching, or using HCl or a HF:H₂O₂:CH₃COOH mixture. A removal for example of at least 5 nm can be provided for producing these recesses 41. The recesses 41 are then filled with insulating plugs 43, also referred to as “inner spacers” (FIG. 12). This can be done, for example, by means of a conformal deposition of dielectric material, for example SiN or SiO₂. This deposition is typically followed by dry etching or a combination of dry and wet etching of the dielectric deposited, so as to form insulating plugs 43 blocking access to the layers 10₁, 10₃, 10₅ based on the first material 12.

Once the plugs 43 have been made, selective epitaxy of semiconductor material 48 can be performed from the uncovered ends of the layers 10₂, 10₄, based on the second material 14. Epitaxy can include in situ doping. For example, dopant reservoirs DT1, DT2 of Si:P or SiGe:B can be epitaxially formed from ends of silicon layers. The epitaxy formed may or may not follow preferred crystalline orientations, and the epitaxial fronts from the different Si layers may possibly meet, as in the exemplary embodiment shown in FIG. 13, to form semiconductor blocks or clusters 49.

Superimposed gates can then be formed.

For this purpose, one method consists first of all in implementing an insulating encapsulation 52 around the gate patterns. Insulating encapsulation 52 can be made, for example, by depositing a PMD-type material (“Pre Metal Dielectric”) such as for example SiO₂ over the entire structure, followed by a CMP planarisation step. This step is preferably carried out so that the polishing front stops at the top of the structure 16 of active zone. This enables the material 22 of the gate patterns to be uncovered, typically a conductive gate material such as polysilicon.

Then (FIG. 15) partial etching of the material 22 of the gate patterns is performed. Partially removing the gate material 22 is performed in such a way as to retain a lower block 24 of gate material and to make cavities 54 surrounded by the encapsulation 52 and disposed above this lower block 24 of gate material. Dry etching or chemical etching, in particular wet etching using TMAH (“Tetramethylammonium hydroxide”) is in particular implemented when the material 22 is polySi.

Etching is performed in such a way as to control the height of the lower block 24 of gate material relative to that of the semiconductor layers of the structure 16 of active zone. Partial removal is implemented so that this block 24 for forming a lower gate GI faces only a single layer 102 based on the second material 14, in particular the lower-level semiconductor layer for accommodating quantum dots or qubits.

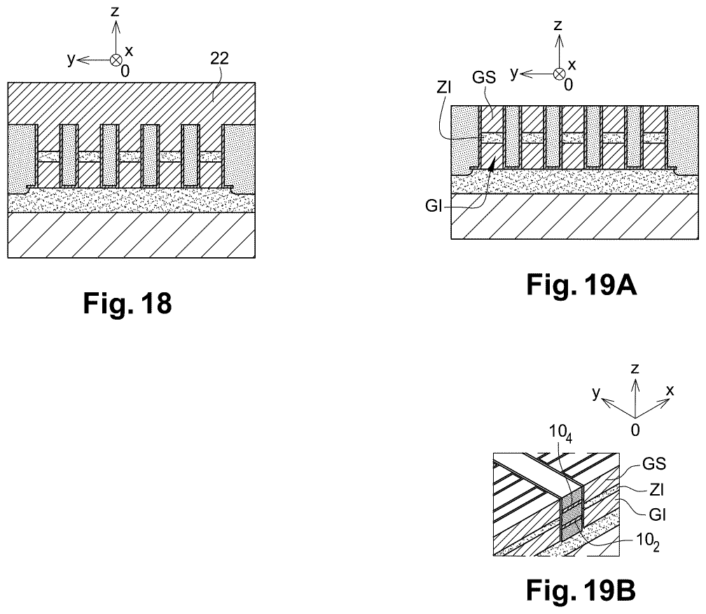

These cavities 54 are then filled (FIG. 16) with at least one layer of insulating material 56, for example SiO₂. This deposition is optionally followed by planarisation and etching to partially remove the insulating material 56 deposited (FIG. 17). The insulating material 56 serves to form an insulation zone ZI for insulating the stages of superimposed gates from each other. A new layer of conductive material, advantageously based on the same conductive material 22 as the lower gate GI, for example polysilicon, is then deposited (FIG. 18) so as to fill the cavities 54. Planarisation is then typically carried out using CMP (FIGS. 19A, 19B) to thus form an upper gate GS.

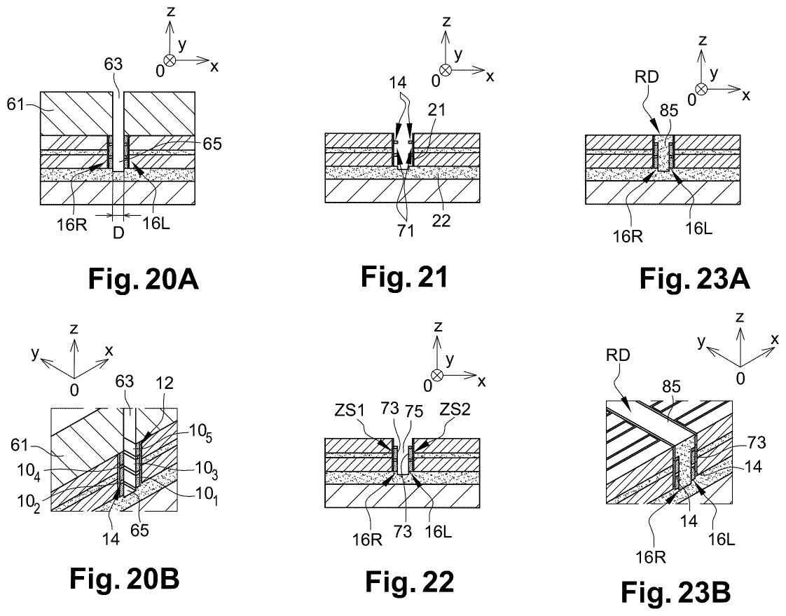

A separation trench 65 is then made (FIGS. 20A, 20B) in order to divide the structure 16 of active zone into two distinct portions 16R, 16L. The trench 65 is typically made until it reaches the substrate 5 through the opening 63 of a masking 61. The trench 65 mainly extends in a direction parallel to the given axis y in FIGS. 20A and 20B, also corresponding to the main direction in which the first portion 16A and the second portion 16B extend.

The masking 61 is for example formed from a stack of lithographic resin typically comprising a photosensitive resin formed on a non-reflecting layer itself formed on a so-called “planarising” layer, typically organic and for example of the SOC type (standing for “Spin-On-Carbon”). Etching the trench is typically anisotropic, for example using a fluorocarbon plasma.

According to one particular exemplary embodiment, the width D (dimension measured parallel to the axis x in FIG. 20A) of the trench 65 corresponding to the distance between the portions 16R, 16L has a dimension of between 30 nm and 60 nm, for example of the order of 50 nm. This trench 65 results in obtaining two portions 16R, 16L facing each other, each formed of a same alternation of layers of a first material and a second material, for example SiGe and Si.

In the particular exemplary embodiment in which, rather than being based on an insulating material, a first semiconducting material 12 is used for the layers 10₁, 10₃, 10₅ of the stack on the basis of which the portions 16R, 16L are each formed, it may be provided to replace this semiconductor material 12 with a dielectric material in order to form separation zones between the various levels of layers 10₂, 10₄ based on the second material 14.

Thus, in this case, removal of the layers 10₁, 10₃, 10₅ based on the first material 12 is first carried out (FIG. 21) by selective etching with respect to the second material 14. In the case where the first material 12 is SiGe and the second material 14 is silicon, this selective removal of the SiGe in order to release silicon can be implemented by selective anisotropic etching of the layers of SiGe, for example by wet chemical method and based on HCl or HF:H₂O₂:CH₃COOH.

Spaces 71 between regions based on the second material 14 are thus released. The dopant reservoirs (not visible in FIG. 21) can then participate in maintaining the semiconductor regions based on the second material 14.

This is then filled with a dielectric material 73 to form insulating “separation” zones ZS1, ZS2.

The dielectric material of the insulating zones ZS1, ZS2 is selected in particular in terms of permittivity or dielectric constant of this material depending on whether or not it is wished to favour coupling in the vertical direction (direction parallel to the axis z) between successive semiconductor stages of material 14 in the portions 16A, 16B.

The insulating zones ZS1, ZS2 are typically made by conformal deposition of dielectric material 73 and then anisotropic etching or a combination of anisotropic/isotropic etching(s) of this dielectric material 73 so as to retain this dielectric material 73 only in spaces situated in vertical alignment with the remaining regions of the semiconductor layers 10₂, 10₄ based on the second material 14 (FIG. 22). A remaining unfilled empty volume forming a reduced trench 75 is thus made between the two portions 16R, 16L of structure 16 of active zone.

The dielectric region RD is then formed (FIGS. 23A and 23B) separating the first portion 16R provided with a first set of semiconductor regions based on the second material 14 from the second portion 16L provided with a first set of semiconductor regions based on the second material 14.

For this, a conformal deposition of dielectric material 85 and then a CMP planarisation of this dielectric material 85 are typically performed so as to fill the remaining empty volume forming a reduced trench 75 separating the two portions 16R, 16L. Two sets of semiconductor regions facing each other are then separated by this dielectric material 85. Here again, the dielectric and its permittivity are selected so as to promote or not promote coupling in the horizontal direction (parallel to the axis x) between the two arrays of semiconductor regions facing each other.

In the exemplary method embodiment just given, for the implementation of superimposed gates GI, GS, lower gates GI formed from the same material 22 as the upper gates GS are provided. Alternatively, it is however possible to provide different materials between the lower gates GI on the one hand and the upper gates GS on the other hand.

Likewise, in the exemplary embodiment just given, the gates formed against the portion 16R of active zone dedicated, for example, to accommodating quantum dots are based on the same material as those located against the portion 16L of active zone facing it and which is dedicated, for example, to accommodating detection islands.

Alternatively, it is however possible to provide different materials between the gates located against the portion 16R on the one hand and the gates located against the portion 16L on the other hand. Such an alternative can be made to obtain different output works and consequently different operating regimes between, for example, gates controlling quantum dots and gates controlling detection islands. To implement such an alternative, one or more lithography steps and one or more additional deposition steps may be provided.

As an alternative to the exemplary method embodiment just given for the implementation of the superimposed gates GI, GS, which describes an approach of the type commonly referred to as “gate-last” in which at least partial replacement of patterns is carried out with a stack having gates separated by an insulation zone, it may be envisaged making this stack directly.

Thus, according to one alternative embodiment of the gates, a “gate-first” approach can be provided. In this case, directly after the step of forming the structure 16 of active zone described previously in connection with FIGS. 6A-6B, provision can be made for making a stack of layers to form the lower gate, the insulation zone, and then the upper gate. The thicknesses of the conducting or semiconducting layers of gate material(s) and of the insulating layer sandwiched between them are then preferably adjusted according to those of the layers of first material 12 and second material 14 of the structure 16 so that each layer of gate material is disposed opposite and in the same plane parallel to the main plane of the substrate as a layer based on the second semiconductor material 14 and in which quantum dots or detection islands are provided.

In either of the exemplary embodiments just described, contact on different gate levels as well as on different semiconductor layer levels can be made, for example, by providing a staircase shape at the ends of the gate structures or portions of active zone.

In a quantum device as described previously, where horizontal interactions are promoted (in other words in directions parallel to the main plane of the substrate) between, on the one hand, a quantum dot BQ1 (and respectively BQ2) and, on the other hand, a detection island ID1 (and respectively ID2) located in the same horizontal plane as this quantum dot BQ1 (and respectively BQ2), a so-called “diagonal” coupling in a diagonal direction DIAG1 (and respectively DIAG2) between a quantum dot BQ1 (and respectively BQ2) and a detection island ID2 (and respectively ID1) located in a different plane to this quantum dot BQ1 (and respectively BQ2) can furthermore be wished to be avoided.

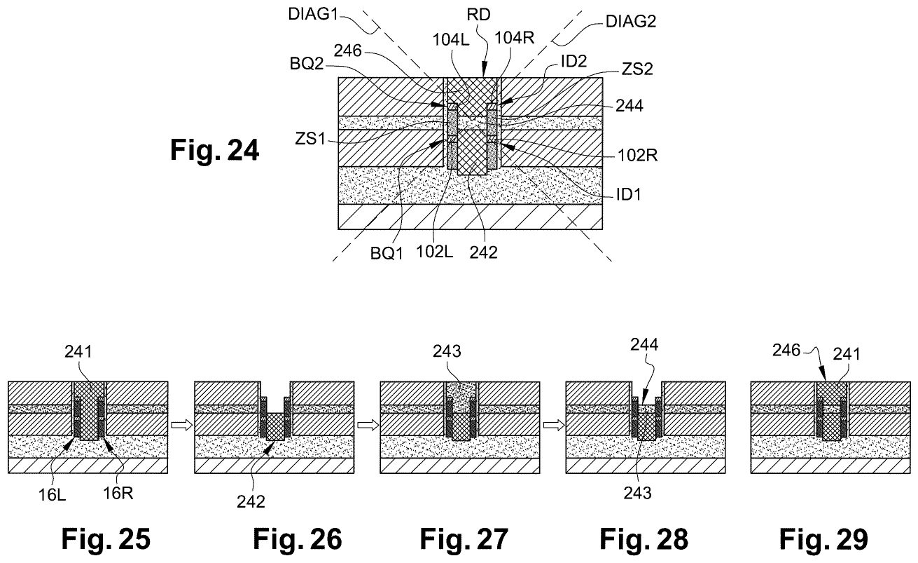

Thus, in an exemplary embodiment illustrated in FIG. 24, a dielectric region RD is thereby provided between the set of semiconductor regions 102R, 104R and the set of semiconductor regions 102L, 104L with herein a heterogeneous composition. A central portion 244 located between a first lower semiconductor region 102R and a second upper semiconductor region 104L and between the first upper semiconductor region 104R and the second lower semiconductor region 102L is based on a dielectric material having a composition and a first relative dielectric permittivity. Another portion 242 of the dielectric region RD located between the first lower semiconductor region 102R and the second lower semiconductor region 102L is provided based on another dielectric material having a composition and a relative dielectric permittivity different from and higher than that of the material of the central portion 244. A portion 246 of the dielectric region RD located this time between the first upper semiconductor region 104R and the second upper semiconductor region 102L is also provided based on a dielectric material having a composition and a relative dielectric permittivity higher than that of the material of the central portion 244.

An exemplary method for making this type of device is illustrated in FIGS. 25 to 29.

A structure as described in connection with FIG. 22 can first be used. And then (FIG. 25) a dielectric material 241 is deposited so as to fill the space separating the two portions 16R, 16L. This dielectric material 241 can then be planarised, for example by CMP (Chemical Mechanical Planarisation, i.e. chemical mechanical polishing).

The dielectric material 241, for example such as SiN or HfO₂, is then partially removed (FIG. 26) typically by wet etching using H₃PO₄ in the case of SiN or plasma CH₂F₂, SF₆ in the case of SiN, CF₄/Ar in the case of HfO₂ in order to form the lower portion 242 of the insulation region.

Another dielectric material 243 is then deposited, typically with a dielectric permittivity lower than the dielectric permittivity of the dielectric material 241 (FIG. 27). The other dielectric material 243 can be SiO₂, for example, and form the central portion 244 of the dielectric region RD.

An optional planarisation by CMP of this other material 243 is then performed.

In the particular exemplary embodiment illustrated in FIG. 28, partial removal is then carried out, typically by wet etching using HF or CF₄ plasma, of this other material 243 in order to form the central portion 244 of the dielectric region RD.

The dielectric material 241 can then be deposited again to form an upper portion 246 of the dielectric region RD (FIG. 29) which, in this example, has a composition identical to that of the lower portion 242. This dielectric material 241 can then be planarised, for example by CMP.

Alternatively, the upper portion 246 may be formed from a third dielectric material different from that of the portions 242, 244 but with a dielectric permittivity higher than the dielectric permittivity of the dielectric material 243 of the central portion 244.

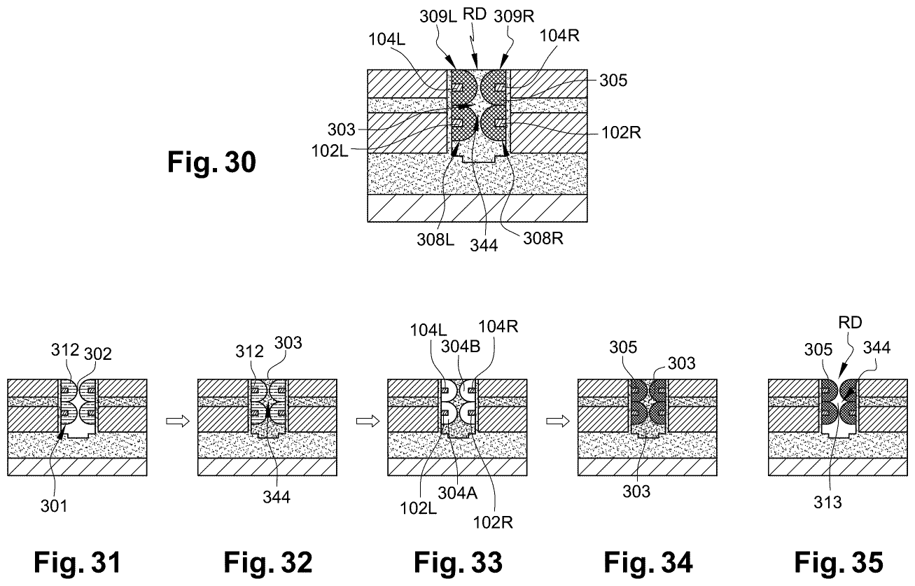

Another example of making a dielectric region RD heterogeneous in terms of dielectric material composition is given in FIG. 30.

The dielectric region RD is here formed by a dielectric material 305 having a dielectric constant k1 cladding each of the first and second lower and upper semiconductor regions 102R, 102L, 104R, 104L, so as to form lower insulating envelopes 308R, 308L against the first and second lower semiconductor regions 102R, 102L and upper insulating envelopes 309R, 309L against the first and second upper semiconductor regions 102R, 104R.

An insulating space formed between the insulating envelopes 308R, 308L 309R, 309L is here filled in by a dielectric material 303 having a second dielectric constant k2 lower than the dielectric constant k1 of the dielectric material 305. A central portion 344 of dielectric material 303 is thus provided to prevent “diagonal” coupling between the semiconductor regions 102L and 104R, and between the semiconductor regions 102R, 104L.

An example method for making this type of device is illustrated in FIGS. 31 to 34.

A structure as described in connection with FIG. 21 obtained after selectively etching the first material 12 in order to release the regions 102R, 102L, 104R, 104L based on the first material 14 can first be used.

First of all (FIG. 31) a semiconductor envelope 301 is formed by epitaxy on the regions 102R, 102L, 104R, 104L based on a sacrificial semiconductor material 312. A semiconductor material 312 is selected to be grown, preferably isotropically, which can be etched selectively with respect to the second material 14. In the particular example illustrated in FIG. 31, this sacrificial semiconductor envelope 301 may be identical to the first material 12, for example SiGe when the material 14 of the regions 102R, 102L, 104R, 104L is silicon. The growth is preferably implemented so as to form semiconductor envelopes and to preserve a space 302 between semiconductor envelopes formed on the first portion 16A of the active-zone structure and the second portion 16B located facing and separated from the first portion 16A.

This space 302 is then filled with a given dielectric material 303 having a given dielectric constant k2, for example SiO₂ (FIG. 32). This can be done by deposition and then CMP planarisation.

Selective removal of the semiconductor envelope 301 based on sacrificial material 312 is then carried out (FIG. 33). In particular, etching of SiGe selectively relative to the silicon can be implemented. Such etching leads to the formation of galleries 304A, 304B around the semiconductor regions 102R, 102L, 104R, 104L based on the first material 14.

The galleries 304A, 304B are then filled with a dielectric material 305 of dielectric constant k1, for example SiN or HfO₂ or Al₂O₃. In particular, an ALD (Atomic Layer Deposition) method can be implemented to avoid any filling defects (FIG. 34).

According to a variant embodiment (FIG. 35), it is possible, in place of the dielectric material 303 of dielectric constant k2, to produce a dielectric region RD separating the two portions 16A, 16B of the active-zone structure, with a space 313 that is empty or filled with air in a central portion 344 of the dielectric region RD and located between the insulating envelopes based on the dielectric material 305 of dielectric constant k1. This can further limit the possibility of diagonal coupling between semiconductor regions 102L, 104R and 104L, 102R.

To implement such an alternative, a structure as obtained previously and described in connection with FIG. 34 can first be used, and then the dielectric material 303 of dielectric constant k2 can be selectively removed from the dielectric material 305 of dielectric constant k1. Such selective removal is carried out, for example, using H₃PO₄ when the dielectric material 303 and the dielectric material 305 are SiN and HfO₂ respectively.

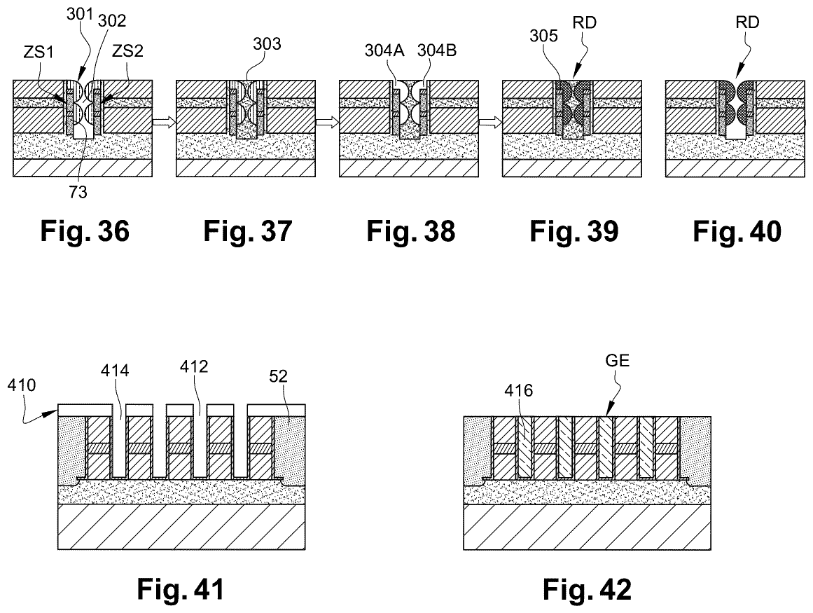

Another exemplary method for making the dielectric region RD between the two portions 16A, 16B of active zone is illustrated in FIGS. 36 to 40.

This time, a structure of the type described in connection with FIG. 22 can first be used to obtain the separation zones ZS1, ZS2 of insulating material 73.

The sacrificial semiconductor envelope 301 is then first of all formed (FIG. 36) by epitaxy on the semiconductor regions 102R, 102L, 104R, 104L.

The dielectric material 303 with dielectric constant k2, for example SiO₂, is then deposited (FIG. 37).

Next, the selective removal of the sacrificial semiconductor envelope 301 based on the first material 12 is implemented (FIG. 38) so as to release volumes in the form of galleries 304A, 304B around the semiconductor regions 102R, 102L, 104R, 104L based on the first material 14.

The galleries 304A, 304B are then filled with a dielectric material 305 of dielectric constant k1, for example SiN or HfO₂ or Al₂O₃, advantageously as a deposition method of the ALD type in order to avoid a filling defect (FIG. 39) to form the dielectric region RD of heterogeneous composition.

As with the exemplary embodiment described previously, the dielectric material 303 of dielectric constant k2 can again optionally then be selectively removed (FIG. 40). An empty space is thus preserved between upper envelopes located on the upper semiconductor regions and between the lower insulating envelopes located respectively on the first and second lower semiconductor regions.

As an alternative to either of the above exemplary methods that have just been described, it may be envisaged making exchange electrodes in inter-gate spaces.

For this, a method illustrated in FIGS. 41 and 42 consists in starting from a structure as obtained after making the gates and described for example previously in connection with FIGS. 19A-19B. A masking 410 is then made, typically of photosensitive resin, in a zone located above the gate block assembly and which includes openings 412 facing inter-gate spaces (FIG. 41). The encapsulating material 52, for example SiO₂, located in the inter-gate spaces is then selectively etched relative to the thin spacer layer 33, for example of SiN, in order to form holes 414. A fluorocarbon dry etching method can be used in particular.

After removing the masking 410, depositing a conductive material 416, for example a TiN/W type stack, is performed to fill the holes 414 thus defined (FIG. 42). This deposition is typically followed by a CMP planarisation step. Planarisation is preferably stopped when the top of the structure of active zone is reached (not visible in FIGS. 41 and 42). In this exemplary embodiment, a single exchange electrode GE per inter-gate space is made.

Alternatively, however, it is possible to form superimposed exchange gates which have an arrangement similar to that of the gate electrodes between which these exchange gates are sandwiched. In each inter-gate space, pairs of superimposed exchange gates separated from each other by an insulator can thus be formed. For this, a method similar to that used to make the gates and described previously in connection with FIGS. 15 to 19A-19B can be employed.

In a variant embodiment, a dielectric region RD is provided between the set of semiconductor regions 102R, 104R and the set of semiconductor regions 102L, 104L with a heterogeneous composition this time making it possible to establish coupling between the first lower semiconductor region 102R and the second upper semiconductor region 104L and between the second lower semiconductor region 102L and the first upper semiconductor region 104R, while preventing coupling between the first lower semiconductor region 102R and the second lower semiconductor region 102L and preventing coupling between the second upper semiconductor region 104L and the first upper semiconductor region 104R.

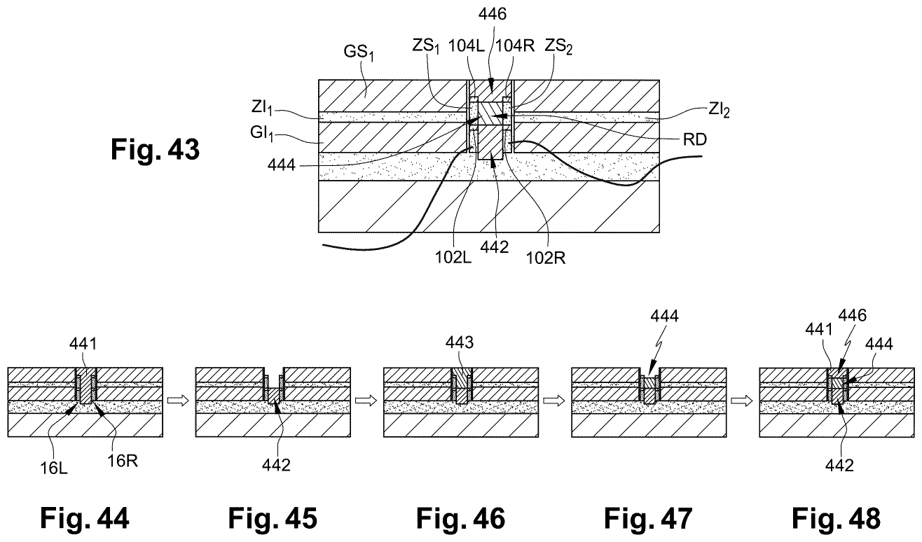

A particular embodiment of this variant is illustrated on FIG. 43. The dielectric region RD includes a dielectric central portion 444 having a composition and a first dielectric permittivity, a lower portion 442 and an upper portion 446 provided respectively based on at least one other dielectric material having a composition and a relative dielectric permittivity different from and lower than that of the material of the central portion 444.

An example method for making this type of device is illustrated in FIGS. 44 to 48. A structure as described in connection with FIG. 22 can be the starting point. Then (FIG. 44) a dielectric material 441 is deposited so as to fill the space separating the two portions 16R, 16L. This dielectric material 441 can then be planarised, for example by CMP (Chemical Mechanical Planarisation, i.e. chemical mechanical polishing). The dielectric material 441, for example such as SiO₂, is then partially removed (FIG. 45) in order to form the lower portion 442 of the dielectric region RD. Another dielectric material 443 is then deposited, typically with a dielectric permittivity higher than the dielectric permittivity of the dielectric material 441 (FIG. 46). The other dielectric material 443 can be for example silicon nitride or HfO₂ and form the central portion 444 of the dielectric region RD. An optional planarisation by CMP of this other material 443 is then performed.

In the particular exemplary embodiment illustrated in FIG. 47, partial removal out of this other material 443 is then implemented in order to form the central portion 444 of the dielectric region RD. The dielectric material 441 can then be deposited again to form an upper portion 446 of the dielectric region RD (FIG. 48) which, in this example, has a composition identical to that of the lower portion 442. This dielectric material 441 can then be planarised, for example by CMP.

In a variant, the upper portion 2446 may be formed from a third dielectric material different from that of the portions 442, 444 but with a dielectric permittivity lower than the dielectric permittivity of the dielectric material 443 of the central portion 444.

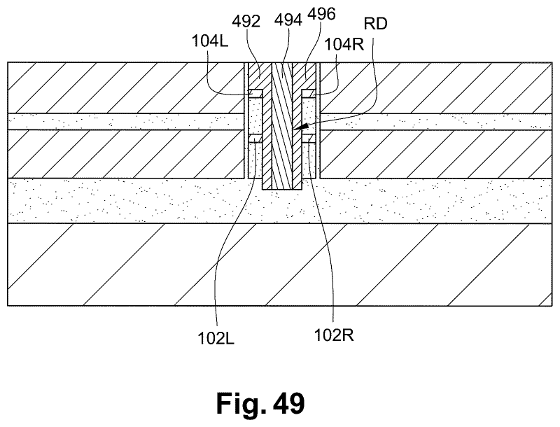

In another variant embodiment illustrated in FIG. 49, a dielectric region RD is provided between the set of semiconductor regions 102R, 104R and the set of semiconductor regions 102L, 104L formed by a juxtaposition of distinct dielectric portions 492, 494, 496. These distinct dielectric portions 492, 494, 496 each extend facing the semiconductor regions 102L, 104L, 102R, 104R.

A central dielectric portion 494 is here interposed between a first dielectric portion 492 and a second dielectric portion 496 with respective compositions different from that of the central dielectric portion 494. The central dielectric portion 494 is made from a given dielectric material 493 having a first dielectric constant, for example HfO₂ or SiN, while the first dielectric portion 492 and the second dielectric portion 496 are based on at least one dielectric material, for example SiO₂, different from said given dielectric material and with respective dielectric constants lower than that of said given dielectric material. For this variant, an electrostatic coupling can be established between superimposed semiconductor regions 102L and 104L or 102R and 104R of one and the same set, while preventing such coupling between semiconductor regions of distinct sets, in other words between distinct superimpositions of semiconductor regions.

1. A quantum electronic device provided with a substrate, the substrate being clad:
with a first set of semiconductor regions, comprising at least one first lower semiconductor region and at least one first upper semiconductor region, superimposed on, and separate from, the first lower semiconductor region by means of a first separation zone, made from dielectric material, and
with a second set of semiconductor regions comprising at least one second lower semiconductor region and at least one second upper semiconductor region, superimposed on, and separated from, the first lower semiconductor region by means of a second separation zone made from dielectric material,
wherein the first set of semiconductor regions is disposed opposite the second set of semiconductor regions so that the first lower semiconductor region is disposed facing the second lower semiconductor region and so that the first upper semiconductor region is disposed facing the second upper semiconductor region, and
at least one dielectric region separates the first set of semiconductor regions from the second set of semiconductor regions, said dielectric region having a heterogeneous composition.

2. The quantum electronic device according to claim 1, said dielectric region being configured so as to allow an electrostatic coupling between the first lower semiconductor region and the second lower semiconductor region, and so as to allow an electrostatic coupling between the first upper semiconductor region and the second upper semiconductor region, and
said dielectric region being provided with a heterogeneous composition so as to prevent an electrostatic coupling between the first lower semiconductor region and the second upper semiconductor region, and so as to prevent an electrostatic coupling between the first upper semiconductor region and the second lower semiconductor region.

3. The device according to claim 1, wherein the dielectric region between the first set of semiconductor regions and the second set of semiconductor regions is configured with a heterogeneous dielectric composition so that, in a central portion located between the first lower semiconductor region and the second upper semiconductor region and between the first upper semiconductor region and the second lower semiconductor region, the dielectric region is formed from a composition with a given dielectric material and a given dielectric constant, and so that, in another portion located between the first lower semiconductor region and the second lower semiconductor region or between the first upper semiconductor region and the second upper semiconductor region, the dielectric region has a second composition and a higher relative dielectric constant than the given dielectric constant.

4. The device according to claim 1, wherein the heterogeneous dielectric region between the first set of semiconductor regions and the second set of semiconductor regions is configured with a heterogeneous dielectric composition so that, in a central portion located between the first lower semiconductor region and the second upper semiconductor region and between the first upper semiconductor region and the second lower semiconductor region, the dielectric region is formed by an empty space, and so that, in another portion located between the first lower semiconductor region and the second lower semiconductor region or between the first upper semiconductor region and the second upper semiconductor region, the dielectric region is formed by a dielectric material.

5. The device according to claim 1, wherein the dielectric region between the first set and the second set of semiconductor regions is formed:
by a lower dielectric portion arranged between the first lower semiconductor region and the second lower semiconductor region,
by an upper dielectric portion located between the first upper semiconductor region and the second upper semiconductor region,
by a central dielectric portion, arranged between the lower dielectric portion and the upper dielectric portion, the lower dielectric portion, the central dielectric portion and the upper dielectric portion being superimposed, and
the central dielectric portion is made from a given dielectric material having a first dielectric constant, the lower dielectric portion and the upper dielectric portion being based on one or more dielectric materials different from said given dielectric material and with respective dielectric constant or constants greater than.

6. The device according to claim 1, wherein the dielectric region with a heterogeneous composition between the first set of semiconductor regions and the second set of semiconductor regions is formed:
by at least one dielectric material having a dielectric constant k1 cladding each of the first and second lower and upper semiconductor regions, so as to form lower insulating envelopes against the first and second lower semiconductor regions and upper insulating envelopes against the first and second upper semiconductor regions, and
at least one insulating space between an upper insulating protrusion located on the first or second upper semiconductor region and a lower insulating protrusion located on the first or second lower semiconductor region, the insulating space being:
filled in by a given dielectric material having a dielectric constant k2, such that k2<k1, or
being an empty space.

7. The quantum electronic device according to claim 1, said dielectric region being provided with a heterogeneous composition so as to allow an electrostatic coupling between the first lower semiconductor region and the second upper semiconductor region and so as to allow an electrostatic coupling between the first upper semiconductor region and the second lower semiconductor region, said dielectric region being configured so as to prevent an electrostatic coupling between the first lower semiconductor region and the second lower semiconductor region and so as to prevent an electrostatic coupling between the first upper semiconductor region and the second upper semiconductor region.

8. The device according to claim 7, wherein the dielectric region between the first set and the second set of semiconductor regions is formed:
by a lower dielectric portion arranged between the first lower semiconductor region and the second lower semiconductor region,
by an upper dielectric portion located between the first upper semiconductor region and the second upper semiconductor region, and
by a central dielectric portion, arranged between the lower dielectric portion and the upper dielectric portion, the lower dielectric portion, the central dielectric portion and the upper dielectric portion being superimposed, the portion central dielectric being made from a given dielectric material having a first dielectric constant, the lower dielectric portion and the upper dielectric portion being based on at least one dielectric material different from said given dielectric material and with a respective dielectric constant less than the first dielectric constant.

9. The quantum electronic device according to claim 1, said dielectric region being configured so as to allow an electrostatic coupling between the first lower semiconductor region and the first upper semiconductor region and so as to allow an electrostatic coupling between the second lower semiconductor region and the second upper semiconductor region, said dielectric region being configured so as to prevent an electrostatic coupling between on the one hand the first lower semiconductor region and on the other hand respectively the second upper semiconductor region and the second lower semiconductor region, and so as to prevent an electrostatic coupling between on the one hand the first upper semiconductor region and on the other hand the second lower semiconductor region and the second upper semiconductor region.

10. The device according to claim 9, wherein the dielectric region between the first set of semiconductor regions and the second set of semiconductor regions is configured with a heterogeneous dielectric composition so that, between the first set of semiconductor regions and the second set of semiconductor regions, the dielectric region is formed by a juxtaposition of a first dielectric portion, a central dielectric portion and a second dielectric portion, the central dielectric portion being arranged between the first dielectric portion and the second dielectric portion, the first dielectric portion, the second dielectric portion and the central dielectric portion each being arranged facing the first lower semiconductor region, the first upper semiconductor region, the second lower semiconductor region and the second upper semiconductor region, the central dielectric portion being made from a given dielectric material having a first dielectric constant, the first dielectric portion and the second dielectric portion being based on at least one dielectric material different from said given dielectric material and with a respective dielectric constant lower than that of the central dielectric portion.

11. The quantum electronic device according to claim 1, said separation zones being configured so as to allow an electrostatic coupling between the first lower semiconductor region and the first upper semiconductor region, and so as to allow an electrostatic coupling between the second lower semiconductor region and the second upper semiconductor region.

12. The quantum electronic device according to claim 1, wherein the first lower semiconductor region and the first upper semiconductor region are regions respectively of a lower semiconductor bar and of an upper semiconductor bar, the lower semiconductor bar and the upper semiconductor bar being disposed one above the other and extending parallel to a first direction parallel to a main plane of the substrate.

13. The quantum electronic device according to claim 12, further comprising a plurality of control gates of the lower semiconductor bar and of the upper semiconductor bar, the control gates extending in a second direction producing a non-zero angle with the first direction and orthogonal to the first direction.

14. The quantum electronic device according to claim 1, further comprising:
a first group of superimposed gates comprising at least a first lower gate and a first upper gate superimposed on and separated from the first lower gate by a first insulation zone, the first lower gate and the first upper gate being disposed against, and facing, respectively, the first lower semiconductor region and the first upper semiconductor region so as to exert electrostatic control of the first lower semiconductor region and of the first upper semiconductor region respectively, and
a second group of superimposed gates comprising at least one second lower gate separated from a second upper gate superimposed on and separated from the second lower gate by a second insulation zone, the second lower gate and the second upper gate being disposed against, and facing, respectively the second lower semiconductor region and the second upper semiconductor region so as to exert respectively an electrostatic control of the second lower semiconductor region and of the second upper semiconductor region, the first group of superimposed gates and the second group of superimposed gates being disposed on either side of the first set of semiconductor regions and of the second set of semiconductor regions.

15. The quantum electronic device according to claim 1, the dielectric region being configured so as to allow an electrostatic coupling between a first semiconductor region from said semiconductor regions of the first set and another given semiconductor region from the semiconductor regions of the first set or of the second set, the first semiconductor region and said other given semiconductor region being located on one and the same first axis, the dielectric region being configured so as to prevent an electrostatic coupling between the first semiconductor region and a different semiconductor region distinct from said other given semiconductor region, said different semiconductor region being located on a second axis passing through said first semiconductor region, the second axis being distinct from the first axis and non-collinear with the first axis.

16. A method for manufacturing a quantum device according to claim 1, wherein forming the first set of semiconductor regions and said second set of semiconductor regions comprises:
producing on said substrate a structure formed by a superimposition of layers composed of an alteration of layers based on a first given material, and of layers based on a second material, the second material being semiconductive, said first given material being able to be etched selectively with respect to the second given material, and
producing a separation trench extending mainly in a direction parallel to the first direction by etching said superimposition of layers so as to divide said structure into a first portion and a second portion, the first portion and the second portion extending parallel to the first direction, the semiconductor regions of the first set being semiconductor regions of the first portion and formed from said second given material, the semiconductor regions of said second set being semiconductor regions of the second portion and formed from said second given material, and
wherein said heterogeneous dielectric region is next formed in the separation trench between said first portion and said second portion of said structure.

17. The method according to claim 16, wherein forming said dielectric region comprises:
depositing in the separation trench a first dielectric material to form a lower dielectric portion arranged between the first lower semiconductor region and the second lower semiconductor region,
depositing in the separation trench a second layer based on a given dielectric material different from the first dielectric material and with a given dielectric constant k2 different from that of the first dielectric material to form a central dielectric portion, and
depositing in the separation trench the first dielectric or a third dielectric material with a dielectric constant different from that of the given dielectric material to form an upper dielectric portion arranged between the first upper semiconductor region and the second upper semiconductor region.

18. The method according to claim 17, wherein, after depositing the first dielectric material and prior to depositing the given dielectric material: a partial removal of the first dielectric material is implemented in the trench, and
wherein, after the given dielectric material is deposited and prior to the formation of the upper dielectric portion, a partial removal of the given dielectric material is implemented.

19. The method according to claim 17, wherein the forming of said dielectric region comprises:
epitaxial growth, on the first lower semiconductor region, the first upper semiconductor region, the second lower semiconductor region and the second upper semiconductor region, of a sacrificial semiconductor material so as to preserve an empty space between the first portion and the second portion of the structure,
filling said empty space by means of a given dielectric material with the given dielectric constant k2,
removing the sacrificial semiconductor material selectively with respect to that of the first lower semiconductor region, of the first upper semiconductor region, of the second lower semiconductor region and of the second upper semiconductor region, in order to release volumes around respectively the first lower semiconductor region, the first upper semiconductor region, the second lower semiconductor region and the second upper semiconductor region, and
filling in the volumes by means of a dielectric material different from the given dielectric material and having a dielectric constant k1 greater than k2.

20. The method according to claim 17, wherein the forming said dielectric region comprises:
epitaxial growth, on the first lower semiconductor region, the first upper semiconductor region, the second lower semiconductor region and the second upper semiconductor region, of a sacrificial semiconductor material so as to preserve an empty space between the first portion and the second portion,
filling said empty space by means of a dielectric material,
removing the sacrificial semiconductor material selectively with respect to that of the first lower semiconductor region, of the first upper semiconductor region, of the second lower semiconductor region and of the second upper semiconductor region, in order to release volumes around respectively the first lower semiconductor region, the first upper semiconductor region, the second lower semiconductor region and the second upper semiconductor region,
filling in the volumes by means of a dielectric material different from the given dielectric material and able to be etched selectively with respect to said given dielectric material, and
removing said given dielectric material selectively with respect to said other dielectric material.
